(19) United States
(12) Patent Application Publication
(10) Pub. No.: US 2025/0155817 A1
(43) Pub. Date: May 15, 2025

(54) SUBSTRATE TREATING APPARATUS

(71) Applicant: SEMES CO., LTD., Cheonan-si (KR)

(72) Inventors: Ki Sang EUM, Cheonan-si (KR); Il Sun YOON, Cheonan-si (KR)

(73) Assignee: SEMES CO., LTD., Cheonan-si (KR)

(21) Appl. No.: 18/930,200

(22) Filed: Oct. 29, 2024

(30) Foreign Application Priority Data
Nov. 15, 2023 (KR) 10-2023-0158060

(51) Int. Cl. G03F 7/20; G03F 7/00

(52) U.S. Cl. CPC G03F 7/2022; G03F 7/7065; G03F 7/70716; G03F 7/70808; G03F 7/70933; G03F 7/70991

(57) ABSTRACT

Disclosed is an apparatus for treating a substrate, the apparatus including: a housing having an entrance through which a substrate is loaded, and having an interior space; a support unit for supporting the substrate in the interior space; and a drive unit for moving the support unit between a first position and a second position; a compartment plate for dividing the interior space into a treatment space and a drive space, and having an opening formed while extending from the first position toward the second position; and an exhaust port connected to the drive space to exhaust an atmosphere in the drive space, and provided to be more adjacent to the second position than to the first position, in which the support unit includes: a support plate which is positioned in the treatment space, and on which the substrate is placed; a support shaft supporting the support plate, and extending from the treatment space to the drive space through the opening; and a blocking plate positioned to overlap the opening when viewed from above, and disposed toward the first position with respect to the support shaft.

### CROSS-REFERENCE TO RELATED APPLICATIONS

This application claims priority to and the benefit of Korean Patent Application No. 10-2023-0158060 filed in the Korean Intellectual Property Office on Nov. 15, 2023, the entire contents of which are incorporated herein by reference.

### TECHNICAL FIELD

The present invention relates to an apparatus for treating a substrate, and more particularly, to an apparatus for inspecting a defect of a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

After the application process is completed, the substrate W may be subjected to a predetermined post-treatment process before the developing process is performed. The post-treatment process may be an Edge Bead Removal (hereinafter referred to as “EBR”) process for removing an edge portion of a photoresist film or circuit pattern, an Edge Exposure of Wafer (hereinafter referred to as “EEW”) process, and an inspection process for performing a predetermined inspection on the substrate W. A chamber for performing an inspection process of a substrate performs the inspection while a support unit supporting the substrate moves relative to a fixed inspection unit, and when the support unit moves in a direction away from an exhaust port formed on one side of the chamber, the atmosphere of a drive space may enter a treatment space and contaminate the substrate in a chamber compartmentalized into the drive space and the treatment space.

### SUMMARY OF THE INVENTION

The present invention has been made in an effort to provide a substrate treating apparatus capable of preventing contamination of a substrate.

The present invention has also been made in an effort to provide a substrate treating apparatus capable of smoothly evacuating an atmosphere in a chamber.

The object of the present invention is not limited thereto, and other objects not mentioned will be clearly understood by those of ordinary skill in the art from the following description.

An exemplary embodiment of the present invention provides an apparatus for treating a substrate, the apparatus including: a housing having an entrance through which a substrate is loaded, and having an interior space; a support unit for supporting the substrate in the interior space; and a drive unit for moving the support unit between a first position and a second position; a compartment plate for dividing the interior space into a treatment space and a drive space, and having an opening formed while extending from the first position toward the second position; and an exhaust port connected to the drive space to exhaust an atmosphere in the drive space, and provided to be more adjacent to the second position than to the first position, in which the support unit includes: a support plate which is positioned in the treatment space, and on which the substrate is placed; a support shaft supporting the support plate, and extending from the treatment space to the drive space through the opening; and a blocking plate positioned to overlap the opening when viewed from above, and disposed toward the first position with respect to the support shaft.

In the exemplary embodiment, the apparatus may further include: a treating unit treating the substrate; and an inspection unit inspecting a defect of the substrate.

In the exemplary embodiment, the treating unit may include an edge exposure unit exposing an edge of the substrate.

In the exemplary embodiment, the blocking plate may be located in the drive space.

In the exemplary embodiment, the blocking plate may be provided only in a direction facing the first position between a direction facing the first position and a direction facing the second position with respect to the support shaft.

In the exemplary embodiment, the blocking plate may be positioned adjacent to the compartment plate, and may be provided not to be in contact with the compartment plate.

In the exemplary embodiment, a width of the blocking plate may be provided to be greater than a width of the opening.

In the exemplary embodiment, the entrance may be provided to be more adjacent to the first position than to the second position.

In the exemplary embodiment, when the support unit is in the first position, the blocking plate may be provided to extend further in a direction toward the entrance than one end of the opening when viewed from above.

In the exemplary embodiment, the drive unit may include: a first driver positioned in the drive space, and rotating the support shaft; and a second driver moving the support shaft in a straight line between the first position and the second position.

In the exemplary embodiment, an average pressure of the drive space may be lower than an average pressure of the treatment space.

Another exemplary embodiment of the present invention provides an apparatus for treating a substrate, the apparatus including: a housing having an entrance through which a substrate is loaded, and having an interior space; a support unit for supporting the substrate in the interior space; and a drive unit for moving the support unit between a first position and a second position and for rotating the support unit; a compartment plate for dividing the interior space into a treatment space and a drive space, and having an opening formed while extending from the first position toward the second position; and an exhaust port connected to the drive space to exhaust an atmosphere in the drive space, and provided to be more adjacent to the second position than to the first position; and an inspection unit for inspecting a defect of the substrate, in which the support unit includes: a support plate which is positioned in the treatment space, on which the substrate is placed; a support shaft supporting the support plate and extending from the treatment space to the drive space through the opening; and a blocking plate positioned to overlap the opening when viewed from above, and disposed toward the first position with respect to the support shaft, and the drive unit may include: a first driver positioned in the drive space, and rotating the support shaft; and a second driver moving the support shaft in a straight line between the first position and the second position, and the entrance is provided to be more adjacent to the first position than to the second position.

In the exemplary embodiment, the apparatus may further include an edge exposure unit exposing an edge of the substrate.

In the exemplary embodiment, the blocking plate may be located in the drive space.

In the exemplary embodiment, the blocking plate may be provided only in a direction facing the first position between a direction facing the first position and a direction facing the second position with respect to the support shaft.

In the exemplary embodiment, a width of the blocking plate may be provided to be greater than a width of the opening.

In the exemplary embodiment, when the support unit is in the first position, the blocking plate may be provided to extend further in a direction toward the entrance than one end of the opening when viewed from above.

Still another exemplary embodiment of the present invention provides an apparatus for treating a substrate, the apparatus including: a housing having an entrance through which a substrate is loaded, and having an interior space; a support unit for supporting and rotating the substrate in the interior space; a drive unit for moving the support unit between a first position and a second position and for rotating the support unit; a compartment plate for dividing the interior space into a treatment space and a drive space, and having an opening formed while extending from the first position toward the second position; an exhaust port connected to the drive space to exhaust an atmosphere in the drive space, and provided to be more adjacent to the second position than to the first position; and an inspection unit for inspecting a defect of the substrate; and an edge exposure unit for exposing an edge of the substrate, in which the support unit includes: a support plate which is positioned in the treatment space, on which the substrate is placed; a support shaft supporting the support plate and extending from the treatment space to the drive space through the opening; and a blocking plate positioned to overlap the opening when viewed from above, and disposed toward the first position with respect to the support shaft, and the drive unit includes: a first driver positioned in the drive space, and rotating the support shaft; and a second driver moving the support shaft in a straight line between the first position and the second position, and the entrance is provided to be more adjacent to the first position than to the second position.

In the exemplary embodiment, the blocking plate may be located in the drive space, and may be provided only in a direction facing the first position between a direction facing the first position and a direction facing the second position with respect to the support shaft.

In the exemplary embodiment, a width of the blocking plate may be provided to be greater than a width of the opening, and when the support unit is in the first position, the blocking plate may be provided to extend further in a direction toward the entrance than one end of the opening when viewed from above.

According to the exemplary embodiment of the present invention, contamination of the substrate may be prevented.

Further, the atmosphere in the chamber may be exhausted smoothly.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a top plan view of a post-treating chamber of FIG. 3.

FIG. 7 is a cross-sectional view of FIG. 6 taken along line A-A′.

FIG. 8 is a diagram schematically illustrating a view of the inside of the post-treating chamber while a support unit is moving from a first position to a second position.

FIG. 9 is a diagram schematically illustrating a view of the inside of the post-treating chamber when the support unit is located in the second position.

FIG. 10 is a diagram schematically illustrating a view of the inside of the post-treating chamber while the support unit is moving from the second position to the first position.

FIG. 11 is a diagram schematically illustrating a view of the inside of the post-treating chamber when the support unit is in the first position.

FIG. 12 is a diagram schematically illustrating a view of the inside of the post-treating chamber when the support unit is not equipped with a blocking plate.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

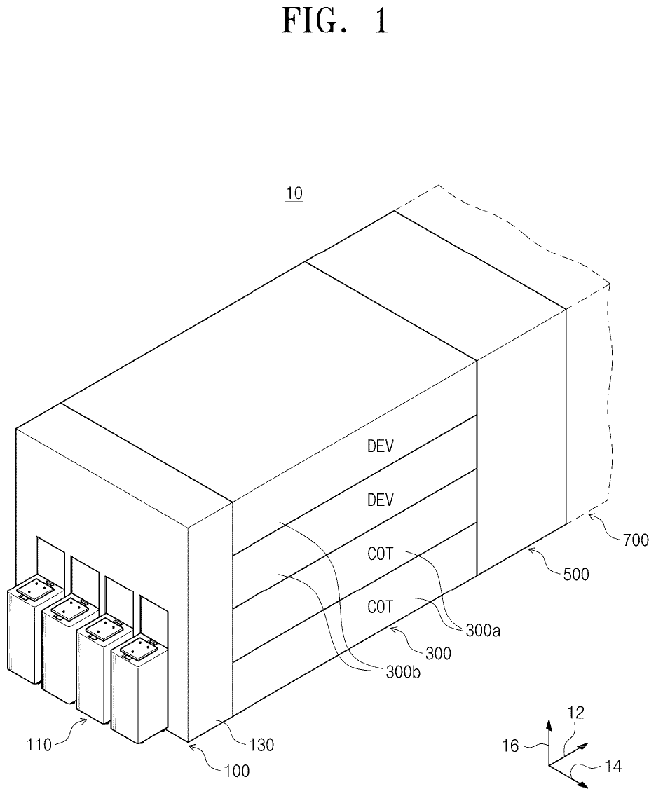

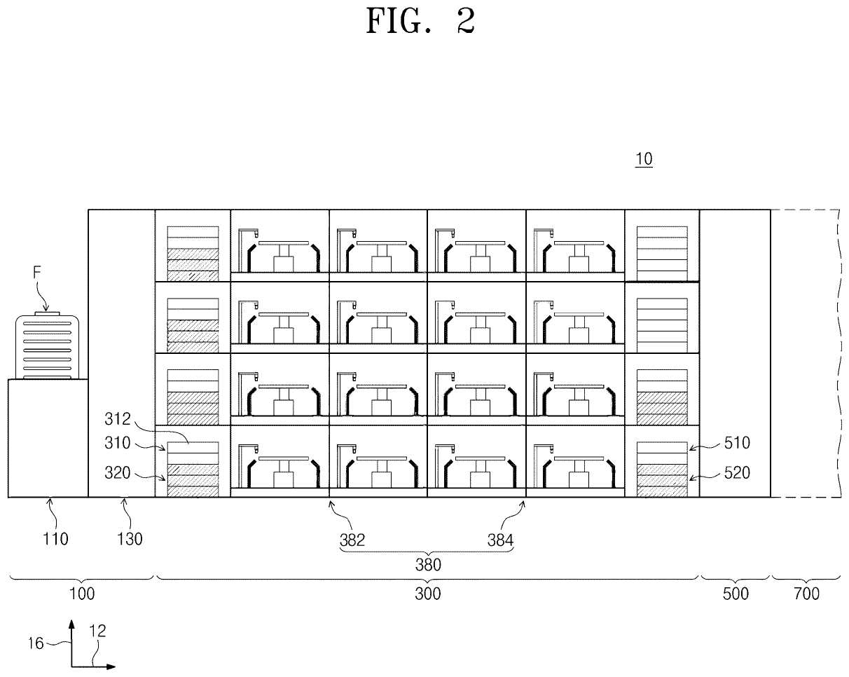

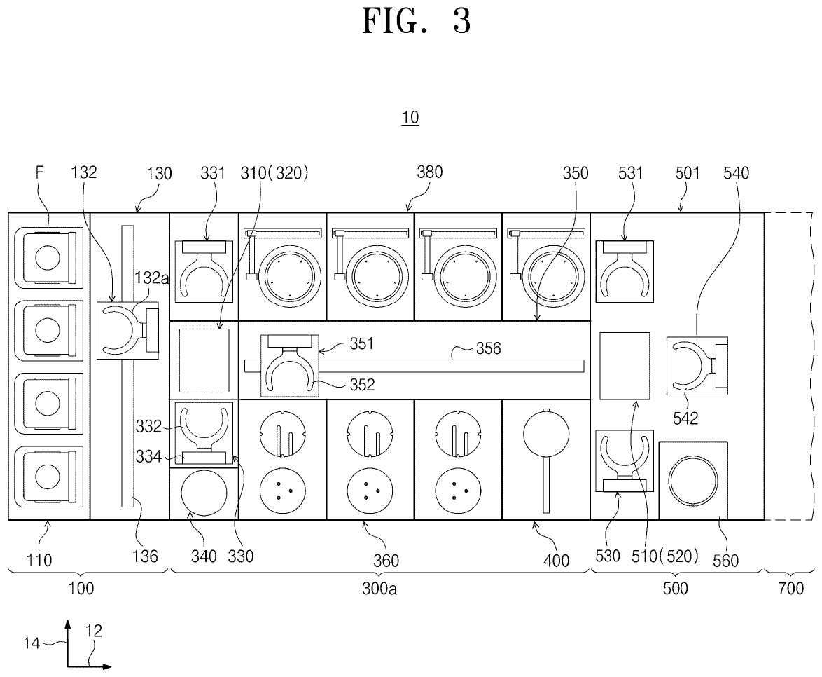

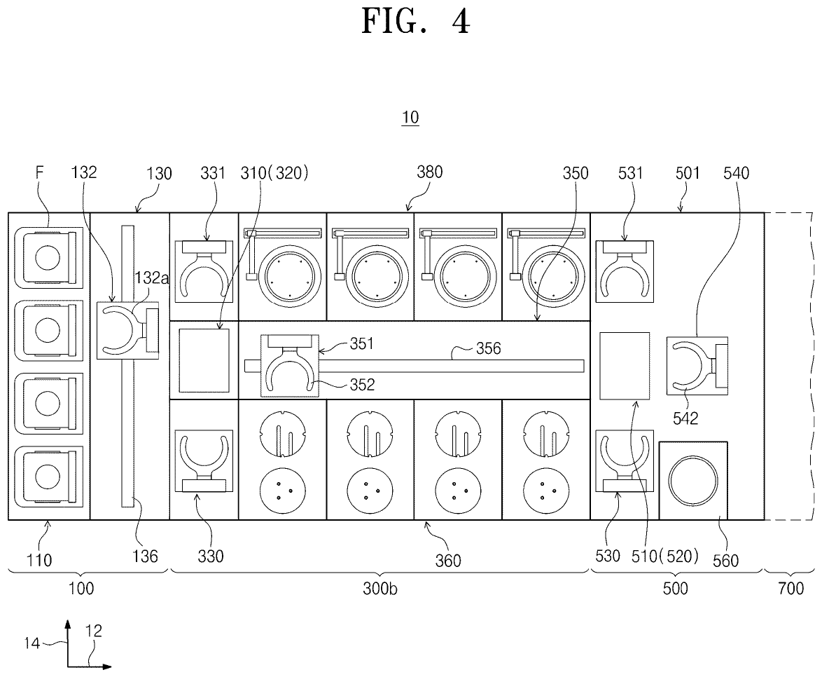

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be positioned below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structure as each other. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 360, a liquid treating chamber 380, and a post-treating chamber 400.

The buffer unit 310, the cooling unit 320, and the hydrophobization chamber 340 are disposed adjacent to the index module 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided with respect to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be positioned adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 1000 may be stacked along the third direction 16.

In one example, the liquid treating chambers 380 include a front end liquid treating chamber 382 and a rear end liquid treating chamber 384 (. The front end liquid treating chamber 382 is disposed relatively close to the index module 100, and the rear end liquid treating chamber 384 is disposed further close to the interface module 500.

The front end liquid treating chamber 382 applies a first liquid onto the substrate W, and the rear end liquid treating chamber 384 applies a second liquid onto the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the applying block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber 380 performs the developing process by supplying a developer onto the substrate W to develop the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 360, the liquid treating chamber 380, the post-treating chamber 400, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

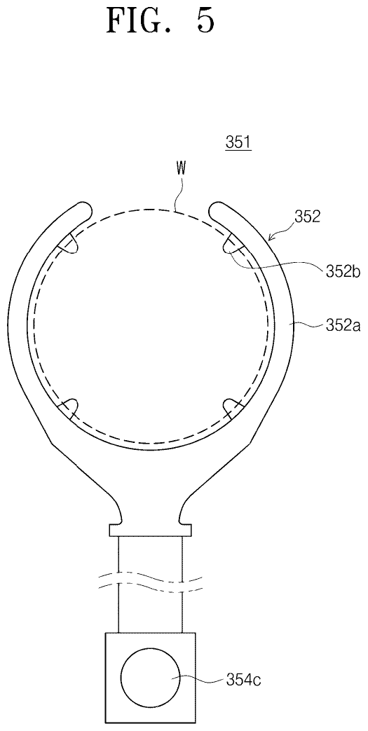

FIG. 5 is a diagram illustrating one example of the hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

The post-treating chamber 400 may perform a post-treatment process on the substrate W that has been processed in the applying block 300a. In one example, the post-treating chamber 400 may perform a post-treating process before the substrate W that has been processed in the applying block 300a is loaded into an exposure device 700. The post-treating process may include an edge exposure process that exposes an edge region of the substrate W, or an inspection process that performs a predetermined inspection on the substrate W. The post-treating chamber 400 may perform both the edge exposure process and the inspection process, or may optionally perform only one of the edge exposure process or the inspection process. The post-treating chamber 400 may optionally perform a post-treating process other than the edge exposure process or the inspection process. A plurality of post-treating chambers 400 may be provided, which may be stacked on top of each other.

Hereinafter, the post-treating chamber 400 will be described.

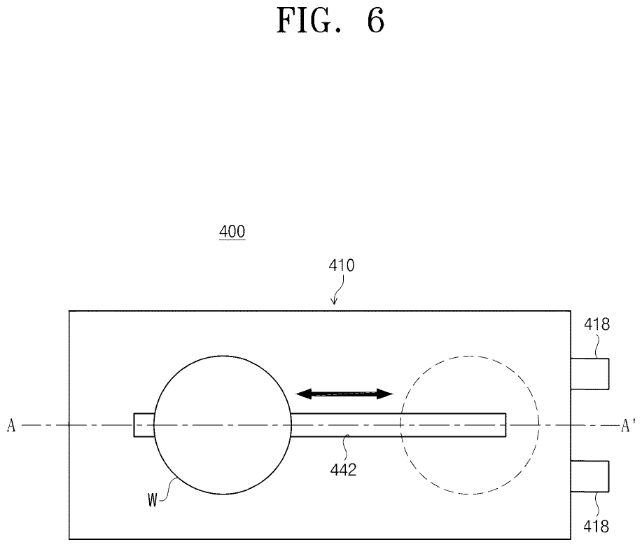

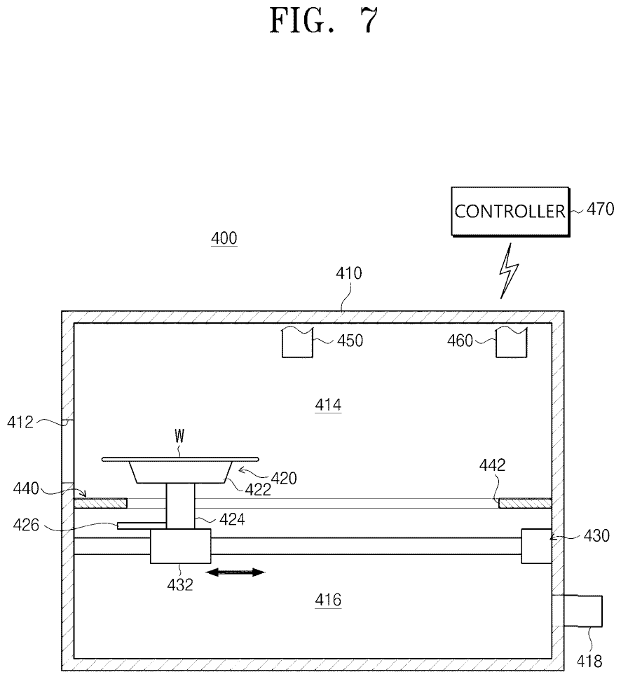

FIG. 6 is a top plan view of the post-treating chamber of FIG. 3, and FIG. 7 is a cross-sectional view of the post-treating chamber of FIG. 6 taken along line A-A′.

Referring to FIGS. 6 and 7, the post-treating chamber 400 includes a housing 410, a support unit 420, a drive unit 430, a compartment plate 440, an inspection unit 450, and a treating unit 460.

The housing 410 has a treatment space 414 and a drive space 416 inside.

On one side of the housing 410, an entrance 412 is formed to load or unload the substrate W. The entrance 412 is equipped with a door (not illustrated) that may be open and closed. The substrate may be loaded into the treatment space 414 through the entrance 412.

The housing 410 includes the compartment plate 440. The compartment plate 440 divides the space inside the housing 410 into the treatment space 414 and drive space 416. Based on the compartment plate 440, the upper portion of the interior space of the housing 410 is divided into the treatment space 414 and the lower portion of the interior space of the housing 410 is divided into the drive space 416. An opening 442 is formed in the compartment plate 440. The opening 442 is formed as an elongated square-shaped slit when viewed from above. The opening 442 extends in a direction from a first position toward a second position. The first position and the second position will be described later.

On one side of the housing 410, an exhaust port 418 that is connected with the drive space 416 to exhaust the atmosphere of the drive space 416 is installed. The exhaust port 418 may be connected to an exhaust pipe outside the housing 410. The exhaust port 418 and the exhaust pipe may be connected to a device, such as a pump, to apply negative pressure to the drive space 416. The exhaust port 418 may exhaust the atmosphere in the drive space 416 to maintain the average pressure in the drive space 416 at a lower pressure than the average pressure of the treatment space 414. The exhaust port 418 is formed in a side wall of the housing 410 opposite the entrance 412, centered on a movement path.

The support unit 420 supports and rotates the substrate W. The support unit 420 includes a support plate 422, a support shaft 424, a blocking plate 426, and a first driver 432. The support plate 422 is provided with a circular top surface. The support plate 422 has a diameter smaller than the substrate W. The support plate 422 is provided to support the substrate W under vacuum pressure. The support shaft 424 is coupled to the center of the bottom surface of the support plate 422, and the support shaft 424 is coupled to a first driver 432 that provides rotational force to the support shaft 424. The first driver 432 may be a motor.

The support plate 422 is located in the treatment space 414, and the support shaft 424 is coupled to the support plate 422 and extends from the treatment space 414 to the drive space 416 through the opening 442.

The support unit 420 is moved in a straight line between the first position and the second position along the movement path by the drive unit 430, which will be described later. The first position is a position of the support unit 420 when the support unit 420 is at one end of the movement path, and the second position is a position of the support unit 420 when the support unit 420 is at the other end of the travel path. Between the first position and the second position, a position adjacent to the entrance 412 will be described herein as the first position and a position distant from the entrance 412 will be described as the second position. As described above, the exhaust port 418 is formed on a side wall of the housing 410 opposite the entrance 412 centered on the movement path, so that the exhaust port 418 is provided closer to the second position than to the first position.

In the state where the support plate 422 is located in the first position, the substrate W is placed on the support plate 422 from the transfer robot 351.

The blocking plate 426 is coupled to the first driver 432. The blocking plate 426 is positioned in the drive space 416. The blocking plate 426 is provided on one side only with respect to the support shaft 424. The blocking plate 426 is formed with respect to the support shaft 424 in a direction facing the side wall facing the side wall on which the exhaust port 418 is formed. Since the exhaust port 418 is provided closer to the second position than the first position, the blocking plate 426 is provided only in the direction facing the first position between the direction facing the first position and the direction facing the second position with respect to the support shaft 424.

The blocking plate 426 is provided adjacent to the compartment plate 440, and is provided parallel to the compartment plate 440. The blocking plate 426 is provided to not contact the compartment plate 440. That is, the blocking plate 426 is provided to have a predetermined gap from the compartment plate 440. The blocking plate 426 is positioned to overlap the opening 442 formed in the compartment plate 440 when viewed from above. The width of the blocking plate 426 is provided to be greater than the width of the opening 442. When the support unit 420 is located in the first position, an end portion of the blocking plate 426 is provided to coincide with one end of the opening 442 when viewed from above, or to extend further in a direction toward the entrance 412 than the one end of the opening 442.

The drive unit 430 is located in the drive space 416. The drive unit 430 moves and rotates the support unit 420. The drive unit 420 includes the first driver 432 described above and a second driver 434. The second motor 434 is configured to move the support unit 420 horizontally between the first position and the second position along the movement path. In one example, the second driver 434 includes a motor to move the support shaft 424 in a straight line and a guide to guide the straight movement of the support shaft 424, and the support shaft 424 is disposed on the guide so that the support unit 420 may move in a straight line along the guide.

The inspection unit 450 is disposed in an upper portion of the treatment space 414 and is installed at a position to inspect the edge of the substrate W placed on the support plate 422.

The inspection unit 450 emits light onto the substrate W supported on the support unit 420 to inspect a defect of the substrate W. The inspection unit 450 is fixedly installed, and the inspection unit 450 inspects a defect of the substrate W while the support unit 420 is being moved from the first position to the second position and/or while the support unit 420 is being moved from the second position to the first position. The inspection unit 450 may acquire an image of the substrate W supported by the support unit 420. The inspection unit 450 may include a line scanner that may scan the surface of the substrate W in a line scan manner as the substrate W moves between the first position and the second position.

The treating unit 460 is disposed above the second position in the treatment space 414 and processes the substrate W. In the present exemplary embodiment, the present invention is described based on the case where the treating unit 460 is an edge exposure unit that exposes the edge of the substrate W as an example. The edge exposure process is performed by the edge exposure unit in the state where the support plate 422 is positioned in the second position.

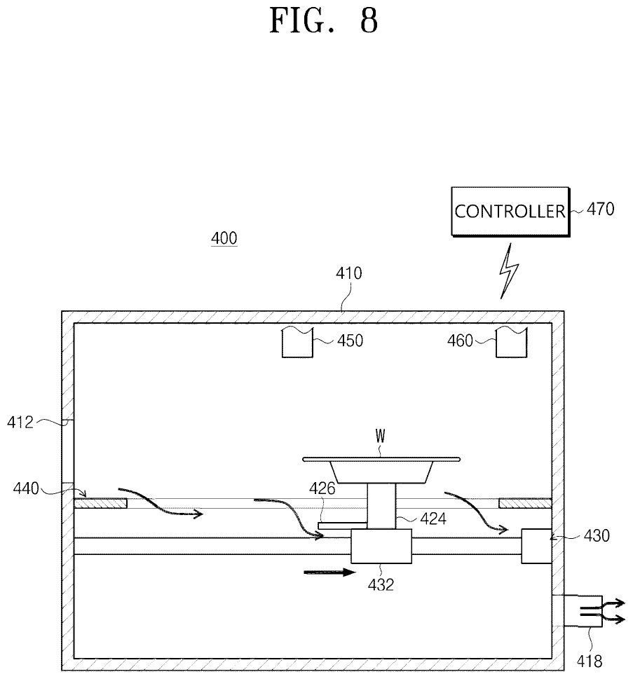

Hereinafter, one exemplary embodiment of a process for treating a substrate in the post-treating chamber of FIG. 7 will be described with reference to FIGS. 8 to 12.

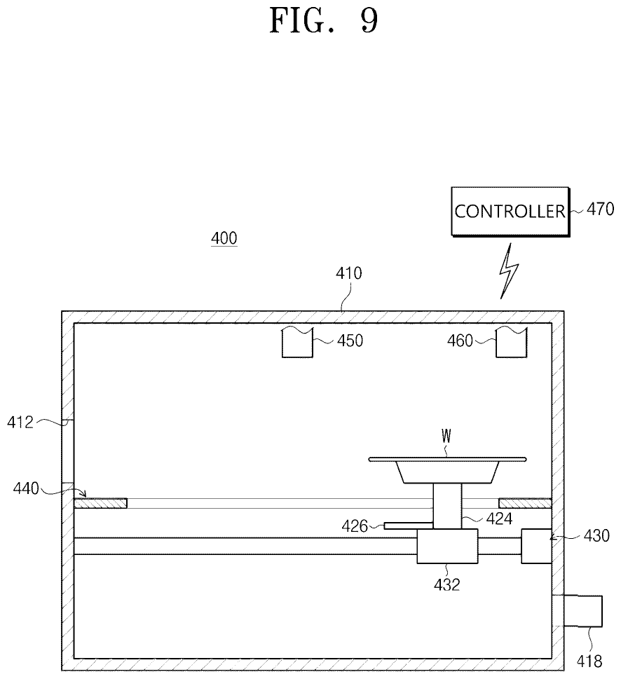

FIG. 8 is a diagram schematically illustrating a view of the inside of the post-treating chamber while the support unit is moving from the first position to the second position. Further, FIG. 9 is a diagram schematically illustrating a view of the inside of the post-treating chamber when the support unit is located in the second position.

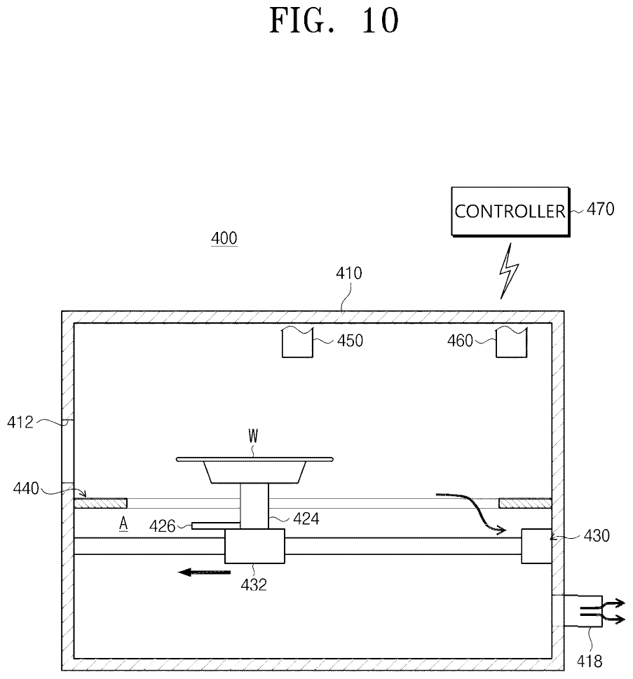

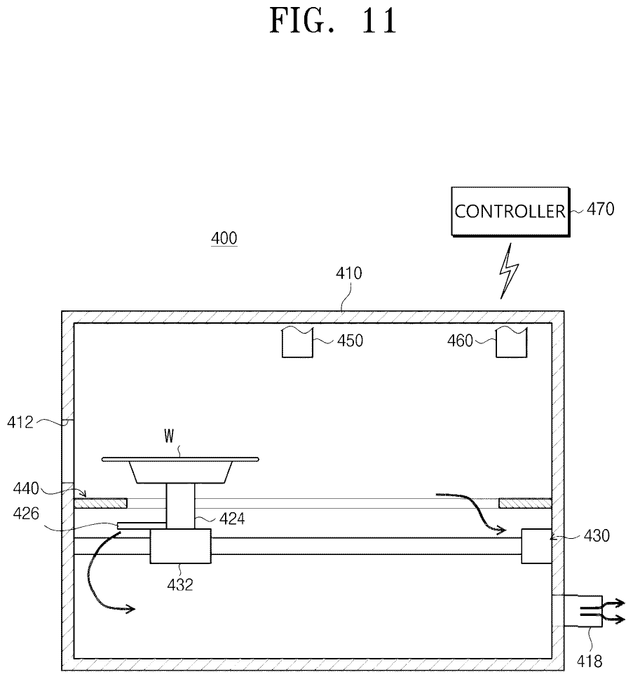

FIG. 10 is a diagram schematically illustrating a view of the inside of the post-treating chamber while the support unit is moving from the second position to the first position, and FIG. 11 is a diagram schematically illustrating a view of the inside of the post-treating chamber when the support unit is in the first position.

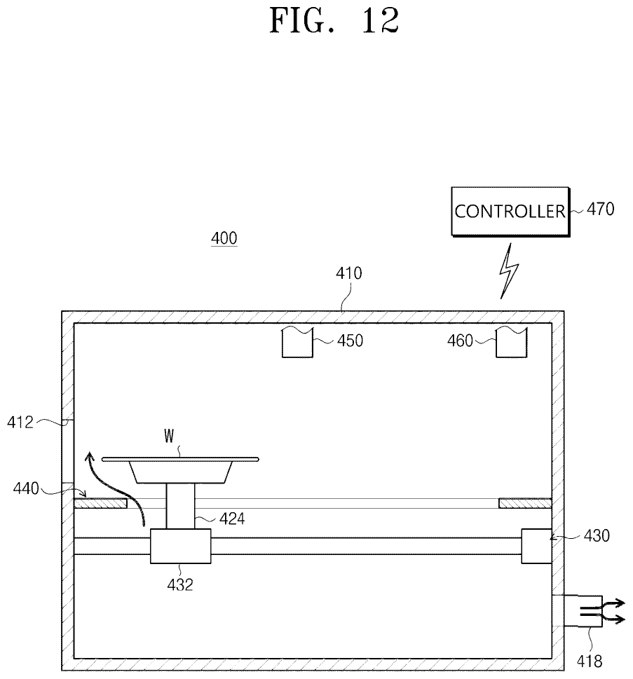

FIG. 12 is a diagram schematically illustrating a view of the inside of the post-treating chamber when the support unit is not equipped with a blocking plate.

By the transfer robot 351 described above, the substrate W is loaded into the post-treating chamber 400, loaded onto the support plate 422 of the support unit 420 located in the first position, and vacuum adsorbed.

The drive unit 430 moves the support unit 420 from the first position to the second position along the movement path. The inspection unit 450 may inspect the state of the substrate W that is moving from the first position to the second position. During the inspection process, the support unit 420 may stop moving, and the substrate W may be rotated by the first driver 432. In one example, the state of the substrate may be that the beads on the edge of the substrate W have been removed.

After the support unit 420 is moved to the second position by the drive unit 430, the edge exposure may proceed. During the rotation of the substrate W by the first driver 432, the edge exposure unit 460 emits light to the edge portion of the substrate W for exposure treatment.

When the substrate edge exposure is complete, the drive unit 430 again moves the support unit 420 from the second position to the first position along the movement path. The inspection unit 450 may inspect the state of the substrate W that is moving from the second position to the first position. During the inspection process, the support unit 420 may stop moving, and the substrate W may be rotated by the first driver 432. In one example, the state of the substrate may be that the edge of the substrate W has been exposed.

The substrate W moved to the first position is unloaded to the outside of the post-treating chamber 400 by the transfer robot 351.

The inspection unit 450 acquires a first image from the substrate W while the substrate W is being moved from the first position to the second position, and acquires a second image from the substrate W while the substrate W is being moved from the second position to the first position after edge exposure. The first image is used to inspect the bead removal state at the edge of the substrate, and the second image is used to inspect the edge exposure state. The inspection unit 450 detects the width of the edge bead removal area or the width of the edge exposure area through image processing, and detects particles. The inspection unit 450 may check the bead removal state at the edge of the substrate through the width of the bead removal area detected in the first image. The inspection unit 450 may check determine the edge exposure state at the edge of the substrate through the width of the photoresist removal area detected in the second image.

During the above process of treating the substrate W within the post-treating chamber 400, the atmosphere inside the drive space 416 is exhausted through the exhaust port 418. Due to the exhaust flow through the exhaust port 418, an airflow is formed from the treatment space 414 through the drive space 416 to the exhaust port 418. Since the exhaust port 418 is formed on a side wall adjacent to the second position, the exhaust direction of the drive space 416 is from the first position to the second position.

In the drive space 416, the drive unit 430 and components, such as electronic devices and wires, are arranged, and due to the horizontal movement of the support unit 420, the atmosphere inside the drive space 416 may flow along the direction of movement of the support unit 420.

Referring to FIG. 8, when the support unit 420 moves from the first position to the second position, the direction of movement of the support unit 420 and the exhaust direction coincide, so that the atmosphere inside the drive space 416 flowing along the direction of movement of the support unit 420 is smoothly exhausted. However, when the support unit 420 moves from the second position to the first position as illustrated in FIG. 10, the movement direction of the support unit 420 is in a direction away from the exhaust direction. Therefore, due to the movement of the support unit 420, the atmosphere inside the drive space 416 may flow along the movement direction of the support unit 420 from the second position to the first position. When the support unit 420 is adjacent to the first position, the pressure in the direction toward the first position may increase centered on the support unit 420. In other words, a compression region A may be generated in which the atmosphere in the region in front of the direction of movement of the support unit 420 is compressed. Accordingly, the atmosphere in the drive space 416 may flow through the opening 442 into the treatment space 414. When the support unit 420 is not provided with the blocking plate 426 as illustrated in FIG. 12, the atmosphere in the drive space 416 may flow backwards when the support unit 420 decelerates while reaching the first position. As a result, various particles generated by the drive unit 430 and the like may flow out of the drive space 416 into the treatment space 414 and contaminate the substrate W.

As described above, the blocking plate 426 is positioned to overlap the opening 442 when viewed from above, and the end portion of the blocking plate 426 is provided to coincide with the one end of the opening 442 or further extend in a direction toward the entrance 412 than the one end of the opening 442.

Thus, as illustrated in FIG. 11, when the support unit 420 is adjacent to the first position, the blocking plate 426 functions to cover the opening 442. This may minimize the introduction of the atmosphere of the drive space 416 into the treatment space 414 through the opening 442. In addition, particles inside the drive space 416 may be blocked from entering the treatment space 414 to prevent contamination of the substrate W. Since the atmosphere in the drive space 416 is prevented from entering the treatment space 414, the atmosphere in the post-treating chamber 400 may be evacuated smoothly.

The interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

A top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may only be provided at a height corresponding to the applying block 300a between the applying block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided with respect to the buffer unit 510.

The interface robot 540 is disposed between the buffer unit 510 and the exposure device 700. The interface robot 540 is provided to transfer the substrate W between the buffer unit 510, the cooling unit 520, the additional process chamber 560, and the exposure unit 700. The interface robot 540 has a hand 542 on which the substrate W is placed, and the hand 542 may be provided to be movable forwardly and backwardly, rotatable about an axis parallel to the third direction 16, and movable along the third direction 16.

The additional treating chamber 560 may perform a predetermined additional process before the substrate W, which has been completely processed in the applying block 300a, is loaded into the exposure device 700. Optionally, the additional treating chamber 420 may perform a predetermined additional process before the substrate W, which has been completely processed in the exposure device 700, is loaded into the developing block 300b. In one example, the additional process may be a top surface cleaning process that cleans the top surface of the substrate W, or a bottom surface cleaning process that cleans the bottom surface of the substrate W. A plurality of additional process chambers 560 is provided, and may be provided to be stacked on each other.

In the exemplary embodiment described above, the present invention has been described as the blocking plate 426 is positioned below the compartment plate 440 and is located in the drive space 416. In contrast, however, the blocking plate 426 may be located above the compartment plate 440, and the blocking plate 426 may be located in the treatment space 416.

In the exemplary embodiment described above, the present invention has been described as the inspection unit 450 is a device that irradiates the substrate W with light to inspect the defect of the substrate W. However, the inspection unit 450 may be any other device that inspects a defect of the substrate W. For example, the inspection unit 450 may be a device that photographs and inspects the substrate W. The inspection unit 450 may include an area camera that photographs a surface of the substrate W by an area scan manner to include a bead removal region and an edge exposure region at the edge of the substrate.

In the exemplary embodiment described above, it has been described as the treating unit 460 disposed above the second position is an edge exposure unit and exposes the edge of the substrate W. However, other processes other than the edge exposure process may be performed within the post-treating chamber 400, and accordingly, the treating unit 460 may be a device that performs other process other than the edge exposure unit.

In the exemplary embodiments described above, it has been described as the post-treating chamber 400 is disposed in the treating module 300. However, alternatively, the post-treating chamber 400 may be disposed in the interface module 500. In this case, the post-treating chamber 400 may be provided to be stacked with the additional process chamber 560 described above.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for treating a substrate, the apparatus comprising:
a housing having an entrance through which a substrate is loaded, and having an interior space;
a support unit for supporting the substrate in the interior space; and
a drive unit for moving the support unit between a first position and a second position;
a compartment plate for dividing the interior space into a treatment space and a drive space, and having an opening formed while extending from the first position toward the second position; and
an exhaust port connected to the drive space to exhaust an atmosphere in the drive space, and provided to be more adjacent to the second position than to the first position,
wherein the support unit includes:
a support plate which is positioned in the treatment space, and on which the substrate is placed;
a support shaft supporting the support plate, and extending from the treatment space to the drive space through the opening; and
a blocking plate positioned to overlap the opening when viewed from above, and disposed toward the first position with respect to the support shaft.

2. The apparatus of claim 1, further comprising:
a treating unit treating the substrate; and
an inspection unit inspecting a defect of the substrate.

3. The apparatus of claim 2, wherein the treating unit includes an edge exposure unit exposing an edge of the substrate.

4. The apparatus of claim 1, wherein the blocking plate is located in the drive space.

5. The apparatus of claim 1, wherein the blocking plate is provided only in a direction facing the first position between a direction facing the first position and a direction facing the second position with respect to the support shaft.

6. The apparatus of claim 1, wherein the blocking plate is positioned adjacent to the compartment plate, and is provided not to be in contact with the compartment plate.

7. The apparatus of claim 1, wherein a width of the blocking plate is provided to be greater than a width of the opening.

8. The apparatus of claim 1, wherein the entrance is provided to be more adjacent to the first position than to the second position.

9. The apparatus of claim 8, wherein when the support unit is in the first position, the blocking plate is provided to extend further in a direction toward the entrance than one end of the opening when viewed from above.

10. The apparatus of claim 1, wherein the drive unit includes:
a first driver positioned in the drive space, and rotating the support shaft; and
a second driver moving the support shaft in a straight line between the first position and the second position.

11. The apparatus of claim 1, wherein an average pressure of the drive space is lower than an average pressure of the treatment space.

12. An apparatus for treating a substrate, the apparatus comprising:
a housing having an entrance through which a substrate is loaded, and having an interior space;
a support unit for supporting the substrate in the interior space; and
a drive unit for moving the support unit between a first position and a second position and for rotating the support unit;
a compartment plate for dividing the interior space into a treatment space and a drive space, and having an opening formed while extending from the first position toward the second position; and
an exhaust port connected to the drive space to exhaust an atmosphere in the drive space, and provided to be more adjacent to the second position than to the first position; and
an inspection unit for inspecting a defect of the substrate,
wherein the support unit includes:
a support plate which is positioned in the treatment space, on which the substrate is placed;
a support shaft supporting the support plate and extending from the treatment space to the drive space through the opening; and
a blocking plate positioned to overlap the opening when viewed from above, and disposed toward the first position with respect to the support shaft, and
the drive unit includes:
a first driver positioned in the drive space, and rotating the support shaft; and
a second driver moving the support shaft in a straight line between the first position and the second position, and
the entrance is provided to be more adjacent to the first position than to the second position.

13. The apparatus of claim 12, further comprising:
an edge exposure unit exposing an edge of the substrate.

14. The apparatus of claim 12, wherein the blocking plate is located in the drive space.

15. The apparatus of claim 12, wherein the blocking plate is provided only in a direction facing the first position between a direction facing the first position and a direction facing the second position with respect to the support shaft.

16. The apparatus of claim 12, wherein a width of the blocking plate is provided to be greater than a width of the opening.

17. The apparatus of claim 12, wherein when the support unit is in the first position, the blocking plate is provided to extend further in a direction toward the entrance than one end of the opening when viewed from above.

18. An apparatus for treating a substrate, the apparatus comprising:
a housing having an entrance through which a substrate is loaded, and having an interior space;
a support unit for supporting and rotating the substrate in the interior space;
a drive unit for moving the support unit between a first position and a second position and for rotating the support unit;
a compartment plate for dividing the interior space into a treatment space and a drive space, and having an opening formed while extending from the first position toward the second position;
an exhaust port connected to the drive space to exhaust an atmosphere in the drive space, and provided to be more adjacent to the second position than to the first position; and
an inspection unit for inspecting a defect of the substrate; and
an edge exposure unit for exposing an edge of the substrate,
wherein the support unit includes:
a support plate which is positioned in the treatment space, on which the substrate is placed;
a support shaft supporting the support plate and extending from the treatment space to the drive space through the opening; and
a blocking plate positioned to overlap the opening when viewed from above, and disposed toward the first position with respect to the support shaft, and
the drive unit includes:
a first driver positioned in the drive space, and rotating the support shaft; and
a second driver moving the support shaft in a straight line between the first position and the second position, and
the entrance is provided to be more adjacent to the first position than to the second position.

19. The apparatus of claim 18, wherein the blocking plate is located in the drive space, and is provided only in a direction facing the first position between a direction facing the first position and a direction facing the second position with respect to the support shaft.

20. The apparatus of claim 18, wherein a width of the blocking plate is provided to be greater than a width of the opening, and
when the support unit is in the first position, the blocking plate is provided to extend further in a direction toward the entrance than one end of the opening when viewed from above.
